(19) United States
(12) Patent Application Publication
(10) Pub. No.: US 2026/0090172 A1
(43) Pub. Date: Mar. 26, 2026

(54) LIGHT EMITTING DEVICE

(71) Applicant: NICHIA CORPORATION, Tokushima (JP)

(72) Inventors: Shohei MORI, Anan-shi (JP); Takeshi TAMURA, Tokushima-shi (JP); Takenori KUMAKURA, Anan-shi (JP)

(21) Appl. No.: 19/330,055

(22) Filed: Sep. 16, 2025

(30) Foreign Application Priority Data
Sep. 20, 2024 (JP) 2024-163967

(51) Int. Cl. H10H 29/851; H01L 25/075; H10H 29/24; H10H 29/85; H10H 29/855

(52) U.S. Cl. CPC H10H 29/8514; H10H 29/24; H10H 29/8508; H10H 29/855; H10W 90/00

(57) ABSTRACT

A light emitting device includes: a support defining first and second recesses partitioned by a wall, an area of a first bottom surface of the first recess is greater than a second bottom surface of the second recess; first and second light emitting elements in the first recess; a third light emitting element in the second recess; a first light transmissive member apart from the third light emitting element in the first recess, including a first wavelength conversion member having an emission peak wavelength longer than the first light emitting element, and overlapping the first and second light emitting elements; and a second light transmissive member located in the second recess and overlapping the third light emitting element.

The first to third light emitting elements are drivable independently.

The emission peak wavelength of the first light emitting element is longer than the second and third light emitting elements.

### CROSS-REFERENCE TO RELATED APPLICATION

The present application claims priority under 35 U.S. C. § 119 to Japanese Patent Application No. 2024-163967, filed Sep. 20, 2024, the contents of which are incorporated herein by reference in their entireties.

### BACKGROUND OF THE INVENTION

### Field of the Invention

This disclosure relates to a light emitting device.

### Description of the Related Art

In general, light emitting devices using light emitting elements, such as light emitting diodes and the like, are widely used as various light sources of lighting fixtures and the like. As such a light emitting device, for example, Japanese Patent Application Laid-Open Publication No. 2022-56834 discloses a light emitting device including: a first light emitting element and a second light emitting element that can be driven independently; a wall separating the first light emitting element and the second light emitting element; a first light transmissive member separated from the second light emitting element by the wall, covering at least a part of a lateral surface of the first light emitting element, and including a first wavelength conversion member; and a second light transmissive member covering the first light emitting element, the second light emitting element, and the first light transmissive member in a top view, and including a second wavelength conversion member, wherein the emission peak wavelength of the first wavelength conversion member is longer than the emission peak wavelength of the second wavelength conversion member.

### SUMMARY OF THE INVENTION

An object of the present disclosure is to provide a light emitting device capable of improving a color mixing performance.

A light emitting device according to an embodiment of the present disclosure includes: a support defining a first recess and a second recess and comprising a wall that partitions between the first recess and the second recess, an area of a first bottom surface defining a bottom of the first recess being greater than an area of a second bottom surface defining a bottom of the second recess in a top view of the light emitting device; a first light emitting element located in the first recess; a second light emitting element located in the first recess; a third light emitting element located in the second recess; a first light transmissive member located in the first recess, the first light transmissive member including a first wavelength conversion member having an emission peak wavelength longer than an emission peak wavelength of the first light emitting element, the first light transmissive member overlapping the first light emitting element and the second light emitting element in the top view and located apart from the third light emitting element in the top view; and a second light transmissive member located in the second recess and overlapping the third light emitting element in the top view, wherein the first light emitting element, the second light emitting element, and the third light emitting element are drivable independently from each other, and wherein the emission peak wavelength of the first light emitting element is longer than an emission peak wavelength of the second light emitting element and an emission peak wavelength of the third light emitting element.

According to an embodiment of the present disclosure, it is possible to provide a light emitting device capable of improving a color mixing performance.

### BRIEF DESCRIPTION OF THE DRAWINGS

FIG. 1A is a schematic top view showing a light emitting device according to a first embodiment;

FIG. 1B is a schematic cross-sectional view along an IB-IB line of FIG. 1A;

FIG. 2 is a schematic top view of the light emitting device shown in FIG. 1 with a first light transmissive member and a second light transmissive member removed;

FIG. 3 is a schematic cross-sectional view showing a light emitting device according to a first modification of the first embodiment;

FIG. 4 is a schematic cross-sectional view showing a light emitting device according to a second modification of the first embodiment;

FIG. 5 is a schematic top view showing a light emitting device according to a third modification of the first embodiment;

FIG. 6 is a schematic cross-sectional view (1) showing a light emitting device according to a fourth modification of the first embodiment;

FIG. 7 is a schematic cross-sectional view (2) showing a light emitting device according to the fourth modification of the first embodiment;

FIG. 8 is a schematic cross-sectional view showing a light emitting device according to a fifth modification of the first embodiment;

FIG. 9 is a schematic cross-sectional view showing a light emitting device according to a sixth modification of the first embodiment; and FIG. 10 is a schematic cross-sectional view showing a light emitting device according to a seventh modification of the first embodiment.

### DETAILED DESCRIPTION OF THE DISCLOSURE

An embodiment for carrying out the invention will be described below with reference to the drawings. In the following description, terms indicating a specific direction or position (for example, “above,” “below,” and other terms including those terms) will be used as necessary. However, the use of these terms is intended to facilitate understanding of the invention with reference to the drawings, and the meaning of these terms does not limit the technical scope of the invention. In addition, parts denoted by the same reference numerals appearing in a plurality of drawings represent the same or equivalent parts or members.

Furthermore, the following embodiment is intended to exemplify a light emitting device and the like for implementing the technical idea of the present invention, and is not intended to limit the invention to the following. The dimensions, materials, shapes, relative positioning, and the like of the components described below are not intended to limit the scope of the present invention only to them, but are intended for exemplification, unless specifically stated. Furthermore, the contents described in one embodiment can be applied to other embodiments and modifications. In addition, the size, positional relationship, and the like of the members shown in the drawings may be exaggerated to clarify the explanation. Furthermore, in order to avoid complicating the drawings excessively, a schematic drawing in which some elements are omitted from illustration may be used, or an end view showing only a sectioned surface may be used as a cross-sectional view.

### First Embodiment

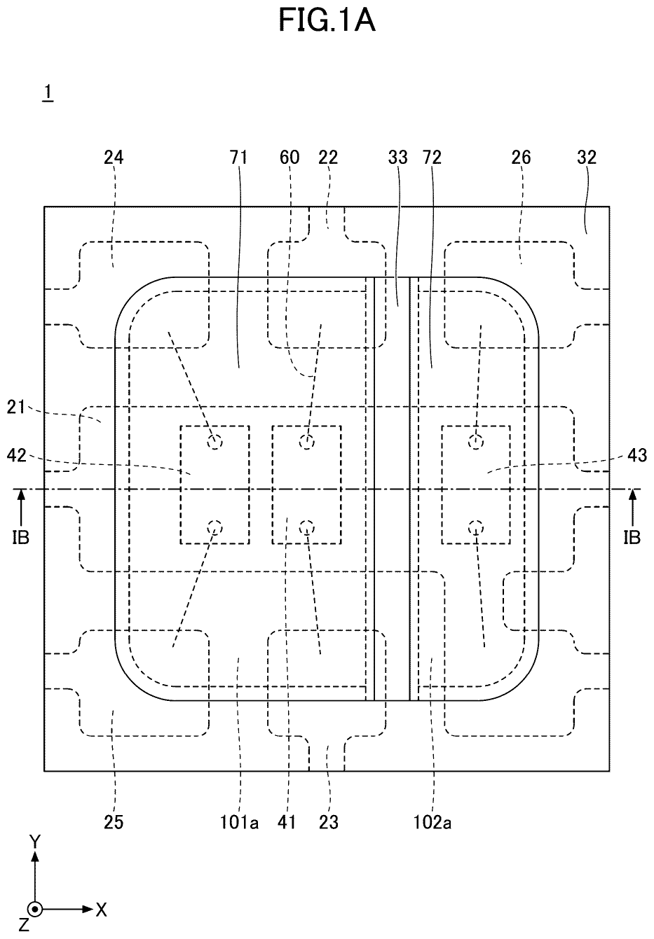

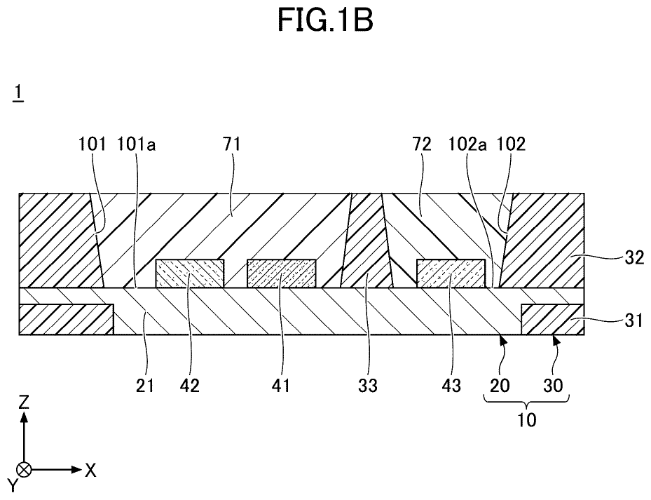

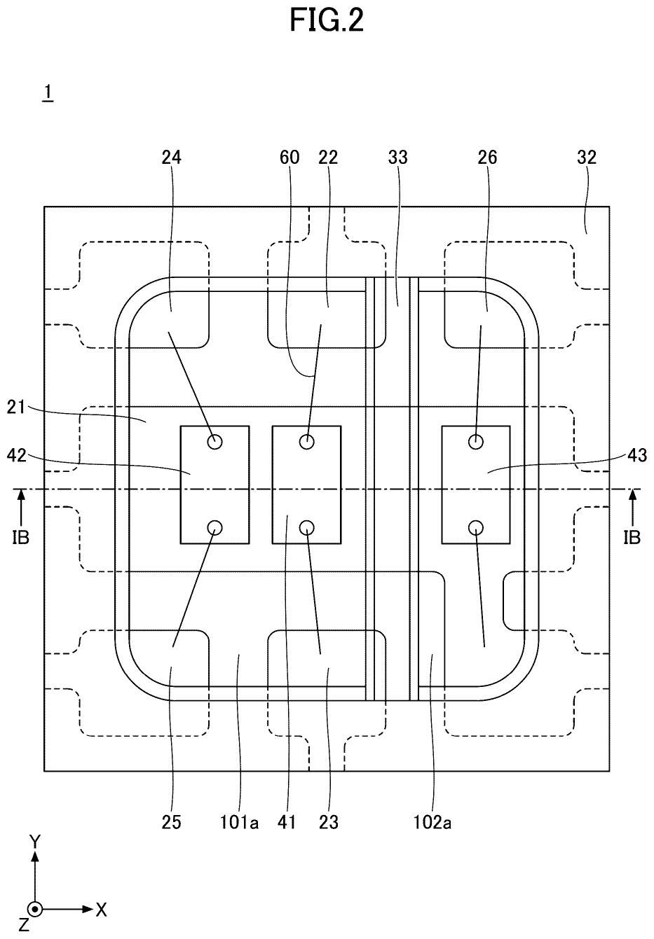

A light emitting device according to the present disclosure includes: a support defining a first recess and a second recess and including a wall that partitions between the first recess and the second recess, an area of a first bottom surface defining a bottom of the first recess being greater than an area of a second bottom surface defining a bottom of the second recess in a top view of the light emitting device; a first light emitting element and a second light emitting element located in the first recess; a third light emitting element located in the second recess; a first light transmissive member located in the first recess, including a first wavelength conversion member having an emission peak wavelength longer than an emission peak wavelength of the first light emitting element, overlapping the first light emitting element and the second light emitting element in the top view, and located apart from the third light emitting element in the top view; and a second light transmissive member located in the second recess and overlapping the third light emitting element in the top view, wherein the first light emitting element, the second light emitting element, and the third light emitting element are drivable independently from each other, and the emission peak wavelength of the first light emitting element is longer than an emission peak wavelength of the second light emitting element and an emission peak wavelength of the third light emitting element.

[Light Emitting Device 1] A light emitting device 1 will be described as an example of the light emitting device according to the present disclosure. FIG. 1A is a schematic top view showing a light emitting device according to the first embodiment. FIG. 1B is a schematic cross-sectional view along an IB-IB line of FIG. 1A. FIG. 2 is a schematic top view of the light emitting device shown in FIG. 1 with a first light transmissive member and the second light transmissive member removed.

In each of the drawings, X, Y, and Z axes orthogonal to each other are shown as necessary for reference. The direction parallel with the X axis is referred to as the first direction X, the direction parallel with the Y axis is referred to as the second direction Y, and the direction parallel with the Z axis is referred to as the third direction Z. In the first direction X, the direction in which the arrow faces is referred to as the +X direction, and the direction opposite to the +X direction is referred to the −X direction. In the second direction Y, the direction in which the arrow faces is referred to as the +Y direction, and the direction opposite to the +Y direction is referred to as the −Y direction. In the third direction Z, the direction in which the arrow faces is referred to as the +Z direction, and the direction opposite to the +Z direction is referred to as the −Z direction. However, these directions do not limit the directions of the light emitting device when the light emitting device is actually used, and the directions of the light emitting device may be selected desirably. Moreover, viewing an object from the +Z direction toward the −Z direction is referred to as viewing the object in a top view.

The light emitting device 1 shown in FIGS. 1A, 1B, and 2 includes: a support 10; a first light emitting element 41, a second light emitting element 42, and a third light emitting element 43; wires 60, a first light transmissive member 71; and a second light transmissive member 72. The first light emitting element 41, the second light emitting element 42, and the third light emitting element 43 may be referred to as light emitting elements.

The support 10 includes a lead 20 and a resin molding 30. The lead 20 is held by the resin molding 30.

The lead 20 has conductivity and can function as an electrode for supplying power to the first light emitting element 41, the second light emitting element 42, and the third light emitting element 43. The lead 20 includes a first lead 21, a second lead 22, a third lead 23, a fourth lead 24, a fifth lead 25, and a sixth lead 26. The first lead 21, the second lead 22, the third lead 23, the fourth lead 24, the fifth lead 25, and the sixth lead 26 are positioned apart from each other via the resin molding 30.

The resin molding 30 may include a bottom portion 31, a frame 32, and a wall 33. The bottom portion 31 covers the lateral surfaces of the leads 20. The frame 32 projects in the +Z direction on the outer periphery of the bottom portion 31, and surrounds the first light emitting element 41, the second light emitting element 42, and the third light emitting element 43 in a top view. The frame 32 may be integral with or separate from the bottom portion 31. In a top view, at a position inward of the frame 32, the wall 33 is located between the first light emitting element 41 and the second light emitting element 42, and the third light emitting element 43. The wall 33 may be integral with or separate from the bottom portion 31. In the present embodiment, the wall 33 and the bottom portion 31 are separate from each other. With reference to the upper surface of the lead 20, the height of the wall 33 may be equal to or greater than 0.9 times and equal to or less than 1.1 times the height of the frame 32. In the present embodiment, the height of the wall 33 is the same as the height of the frame 32.

The support 10 defines a first recess 101 and a second recess 102 that are partitioned from each other by the wall 33. The first recess 101 and the second recess 102 are located inward of the frame 32 in a top view. In this specification, the phrase “located inward of the frame 32 in a top view” means being located closer to the center of the light emitting device 1 than the frame 32 is to the center of the light emitting device 1 in the top view. The term “center of the light emitting device 1 in the top view” means the centroid of the light emitting device 1 in the top view. The first recess 101 is defined by a first bottom surface 101a, an inner lateral surface of the frame 32, and an inner lateral surface of the wall 33. The first bottom surface 101a is constituted by the upper surfaces of the first lead 21, the second lead 22, the third lead 23, the fourth lead 24, and the fifth lead 25, and the upper surface of the bottom portion 31. The second recess 102 is defined by a second bottom surface 102a, an inner lateral surface of the frame 32, and an inner lateral surface of the wall 33. The second bottom surface 102a is constituted by the upper surfaces of the first lead 21 and the sixth lead 26, and the upper surface of the bottom portion 31. In a top view, the area of the first bottom surface 101a defining a bottom of the first recess 101 is greater than the area of the second bottom surface 102a defining a bottom of the second recess 102. The area of the first bottom surface 101a may be equal to or greater than 1.5 times and equal to or greater than 2.5 times the area of the second bottom surface 102a.

The first light emitting element 41 and the second light emitting element 42 are located in the first recess 101. Specifically, the first light emitting element 41 and the second light emitting element 42 are located on the first lead 21 exposed in the first recess 101, and are electrically connected to appropriate positions on the lead 20 by the wires 60. The third light emitting element 43 is located in the second recess 102. Specifically, the third light emitting element 43 is located on the first lead 21 exposed in the second recess 102, and is electrically connected to an appropriate position on the lead 20 by the wires 60.

The emission peak wavelength of the first light emitting element 41 is longer than the emission peak wavelength of the second light emitting element 42 and the emission peak wavelength of the third light emitting element 43. The emission peak wavelength of the second light emitting element 42 and the emission peak wavelength of the third light emitting element 43 may or may not be the same. For example, the first light emitting element 41 may emit green light (having a peak wavelength of 495 nm or greater and 565 nm or less), and the second light emitting element 42 and the third light emitting element 43 may emit blue light (having a peak wavelength of 430 nm or greater and 490 nm or less). The first light emitting element 41, the second light emitting element 42, and the third light emitting element 43 are drivable independently from each other.

The first light emitting element 41 and the third light emitting element 43 may be arranged in the first direction X. In this case, it is preferable that the length of the third light emitting element 43 in the first direction X is shorter than the length of the third light emitting element 43 in the second direction Y orthogonal to the first direction X. Thus, the light emitting device 1 can be reduced in size in the first direction X.

In the illustrated example, the first light emitting element 41, the second light emitting element 42, and the third light emitting element 43 are rectangular in a top view. The longer sides of each of the first light emitting element 41, the second light emitting element 42, and the third light emitting element 43 are parallel with the second direction Y, and the short sides thereof are parallel with the first direction X. The first light emitting element 41, the second light emitting element 42, and the third light emitting element 43 are arranged in the first direction X. In a top view, the center of the first light emitting element 41, the center of the second light emitting element 42, and the center of the third light emitting element 43 may be located on an imaginary straight line parallel with the first direction X. The longer sides of the first light emitting element 41 and the second light emitting element 42 face each other. Since the longer sides of the first light emitting element 41 and the second light emitting element 42 having different emission peak wavelengths face each other, the color mixing performance of the light emitting device 1 is improved.

The first light transmissive member 71 is located in the first recess 101. In the present embodiment, the first light transmissive member 71 includes a first wavelength conversion member having an emission peak wavelength longer than the emission peak wavelength of the first light emitting element 41. For example, in a case where the first light emitting element 41 emits green light (having a peak wavelength of 495 nm or greater and 565 nm or less), the first wavelength conversion member may be a red phosphor (having peak wavelength of 610 nm or greater and 700 nm or shorter).

The first light transmissive member 71 overlaps the first light emitting element 41 and the second light emitting element 42 in a top view and is located apart from the third light emitting element 43 in a top view. The first light transmissive member 71 covers the upper and lateral surfaces of the first light emitting element 41 and the upper and lateral surfaces of the second light emitting element 42. The first light transmissive member 71 is not located in the second recess 102.

The second light transmissive member 72 is located in the second recess 102. The second light transmissive member 72 overlaps the third light emitting element 43 in a top view. The second light transmissive member 72 covers the upper and lateral surfaces of the third light emitting element 43. In the present embodiment, the second light transmissive member 72 does not contain a wavelength conversion member. The phrase “does not contain a wavelength conversion member” does not exclude unavoidable mix of a wavelength conversion member, and means that a content ratio of a wavelength conversion member is, for example, 0.05% by weight or less.

In another embodiment, the first light transmissive member 71 may not contain the wavelength conversion member, and the second light transmissive member 72 may include a first wavelength conversion member having an emission peak wavelength longer than the emission peak wavelength of the first light emitting element 41. When the first light transmissive member 71 includes the first wavelength conversion member, the light emitted by the first light emitting element 41 and the light emitted by the second light emitting element 42 are scattered by the first wavelength conversion member, resulting in increase in light absorption. On the other hand, when the second light transmissive member 72 includes the first wavelength conversion member, only the light emitted by the third light emitting element 43 is scattered by the first wavelength conversion member, resulting in reduction in light absorption. Thus, the light extraction efficiency of the light emitting device 1 can be improved.

At least parts of the upper surface of the frame 32, the upper surface of the wall 33, the upper surface of the first light transmissive member 71, and the upper surface of the second light transmissive member 72 can be on the same plane.

When the light emitting device 1 is driven, a current is supplied to the first light emitting element 41, the second light emitting element 42, and/or the third light emitting element 43 from an external power source via the lead 20, and the first light emitting element 41, the second light emitting element 42, and/or the third light emitting element 43 emit light. Light emitted from the first light emitting element 41, the second light emitting element 42, and the third light emitting element 43 includes light traveling upward, light traveling sideward, and light traveling downward from each light emitting element. Light emitted from the light emitting device 1 includes light emitted from the first light emitting element 41 and passing through the first light transmissive member 71, light emitted from the second light emitting element 42 and passing through the first light transmissive member 71, and light emitted from the third light emitting element 43 and passing through the second light transmissive member 72.

Thus, the light emitting device 1 includes the first light emitting element 41 and the second light emitting element 42 located in the first recess 101, and the third light emitting element 43 located in the second recess 102, and these light emitting elements are drivable independently from each other. Furthermore, the light emitting device 1 includes the first light transmissive member 71 located in the first recess 101, overlapping the first light emitting element 41 and the second light emitting element 42 in a top view, and located apart from the third light emitting element 43 in a top view. The emission peak wavelength of the first light emitting element 41 is longer than the emission peak wavelength of the second light emitting element 42 and the emission peak wavelength of the third light emitting element 43. The first light transmissive member 71 includes the first wavelength conversion member having an emission peak wavelength longer than the emission peak wavelength of the first light emitting element 41.

Such a configuration allows for realizing the light emitting device 1 capable of improving the color mixing performance. Specifically, in one example, the first light emitting element 41 emits green light, the second light emitting element 42 and the third light emitting element 43 emit blue light, and the first wavelength conversion member of the first light transmissive member 71 is a red phosphor. In this case, green light emitted from the first light emitting element 41, red light that has been wavelength-converted by the first light transmissive member 71 from light emitted from the second light emitting element 42, and blue light emitted from the third light emitting element 43 are mixed, causing white light to be emitted from the light emitting device 1. With the area of the first bottom surface defining the first recess larger than the area of the second bottom surface, the volume of the first light transmissive member 71 located in the first recess can be increased more easily compared with a case in which the area of the first bottom surface is smaller than the area of the second bottom surface. Green light emitted from the first light emitting element 41, blue light emitted from the second light emitting element 42, and red light that has been wavelength-converted by the first light transmissive member 71 from light emitted from the second light emitting element 42 are easily mixed in the first light transmissive member 71. This allows for improving the color mixing performance of the light emitting device 1. Moreover, with the area of the first bottom surface defining the first recess larger than the area of the second bottom surface, the area of the first light transmissive member 71 in a top view can be increased compared with a case in which the area of the first bottom surface is smaller than the area of the second bottom surface.

Green light emitted from the first light emitting element 41, blue light emitted from the second light emitting element 42, and red light that has been wavelength-converted by the first light transmissive member 71 from light emitted from the second light emitting element 42 can be mixed in the first light transmissive member 71, which is relatively wide in a top view. As a result, white light can be obtained in a relatively large area.

Details of each member included in the light emitting device 1 will be described below.

### Lead 20

The upper surfaces of the first lead 21, the second lead 22, the third lead 23, the fourth lead 24, the fifth lead 25, and the sixth lead 26 constituting the lead 20 can be partially exposed within the frame 32 in a top view. The upper surfaces of the first lead 21, the second lead 22, the third lead 23, the fourth lead 24, the fifth lead 25, and the sixth lead 26 are, for example, flush with the upper surface of the bottom portion 31. The lower surfaces of the first lead 21, the second lead 22, the third lead 23, the fourth lead 24, the fifth lead 25, and the sixth lead 26 can be exposed from the lower surface of the bottom portion 31 of the resin molding 30. The lower surfaces of the first lead 21, the second lead 22, the third lead 23, the fourth lead 24, the fifth lead 25, and the sixth lead 26 are, for example, flush with the lower surface of the bottom portion 31. When the lower surfaces of the first lead 21, the second lead 22, the third lead 23, the fourth lead 24, the fifth lead 25, and the sixth lead 26 are exposed from the lower surface of the bottom portion 31 of the resin molding 30, heat from the light emitting device 1 is likely to be transmitted to the substrate mounted with the light emitting device 1 through each lead. Therefore, heat dissipation of the light emitting device 1 can be improved. The lower surface of each lead exposed from the lower surface of the bottom portion 31 can be used as an external terminal for electrically connecting to the substrate. The light emitting device 1 may include seven or more leads. The light emitting device 1 may also include a lead that is not electrically connected to the light emitting element.

Examples of the base material of the lead 20 include metals, such as copper, aluminum, gold, silver, iron, nickel, or alloys thereof, phosphor bronze, iron-bearing copper, and the like. As the material of the lead 20, it is particularly preferable to use copper having a high heat dissipation performance. The lead 20 can be formed into a predetermined shape by processing, such as rolling, punching, extrusion, etching by wet or dry etching, a combination thereof, and the like. The lead 20 may be a single layer or a multilayer structure (for example, a clad material).

The lead 20 may have a plated layer on the surface of the base material metal. For the purpose of improving reflectance, the plated layer may be, for example, gold, silver, copper, platinum, aluminum, or an alloy containing one of these. Since gold is less corrosive than silver, the reliability of the light emitting device 1 can be improved when the plated layer contains gold. When the plated layer contains silver, it is preferable to provide a known protective film, such as silicon oxide or the like, on the surface of the plated layer. Thus, it is possible to reduce discoloration of the silver-containing plated layer due to sulfur components or the like in the atmosphere. The protective film may be a single-layer film or a multilayer film. The protective film can be formed by at least one of sputtering method, vapor deposition method, or atomic layer deposition method (ALD method). Among them, the sputtering method is preferable because of its simplicity, and the atomic layer deposition method is preferable in that a dense film with a low water vapor permeability is likely to be formed.

In the first lead 21, the second lead 22, the third lead 23, the fourth lead 24, the fifth lead 25, and the sixth lead 26, grooves may or may not be formed on their side close to the frame 32 in a top view. In the first lead 21, the second lead 22, the third lead 23, the fourth lead 24, the fifth lead 25, and the sixth lead 26, it is preferable to form grooves on their side close to the frame 32 in a top view. The grooves are recessed from the upper surfaces to the lower surfaces of the first lead 21, the second lead 22, the third lead 23, the fourth lead 24, the fifth lead 25, and the sixth lead 26. The grooves can be formed by etching, pressing, and the like. A groove may be formed in at least one of the first lead 21, the second lead 22, the third lead 23, the fourth lead 24, the fifth lead 25, or the sixth lead 26. It is preferable to locate a part of the resin molding 30 in the groove. Thus, close adhesiveness between the resin molding 30 and the first lead 21, the second lead 22, the third lead 23, the fourth lead 24, the fifth lead 25, and/or the sixth lead 26 can be improved.

### Resin Molding 30

In the resin molding 30, the inner lateral surface of the frame 32 may be an inclined surface inclined with respect to the upper surface of the lead 20, or may be a perpendicular surface perpendicular to the upper surface of the lead 20. In the example of the light emitting device 1, the inner lateral surface of the frame 32 has an inclined surface that goes progressively outward at higher vertical levels above the upper surface of the lead 20. Thus, light from the first light emitting element 41, the second light emitting element 42, and the third light emitting element 43 is more easily reflected upward.

The wall 33 is a member partitioning the first recess 101 and the second recess 102 from each other. The wall 33 is located above the upper surface of the lead 20. In the example of the light emitting device 1, the wall 33 extends in the second direction Y continuously to be in contact with the inner lateral surface of the frame 32. The wall 33 does not need to be in contact with the inner lateral surface of the frame 32.

The wall 33 may or may not cover the upper surface of the first lead 21, the upper surface of the second lead 22, and/or the upper surface of the third lead 23.

The wall 33 covering the upper surface of the first lead 21, the upper surface of the second lead 22, and/or the upper surface of the third lead 23 facilitates improving close adhesiveness between the support 10 and the first lead 21, the second lead 22, and/or the third lead 23. The wall 33 not covering the upper surface of the first lead 21, the upper surface of the second lead 22, and/or the upper surface of the third lead 23 enables increasing the area of the lead 20 exposed from the resin molding 30 in the first bottom surface 101a and the second bottom surface 102a. This facilitates locating of the first light emitting element 41, the second light emitting element 42, and/or the third light emitting element 43 on the lead 20.

With the light emitting device 1 including the wall 33, it becomes difficult for the first light transmissive member 71 and the second light transmissive member 72 to contact each other. Moreover, with the light emitting device 1 including the wall 33, it becomes difficult for the light from the first light emitting element 41 and the second light emitting element 42 to impinge on the second light transmissive member 72, and for the light from the third light emitting element 43 to impinge on the first light transmissive member 71. This can secure large differences between the chromaticity obtained when only the first light emitting element 41 emits light, the chromaticity obtained when only the second light emitting element 42 emits light, and the chromaticity obtained when only the third light emitting element 43 emits light. This facilitates widening the color gamut of the light emitting device 1.

In the present embodiment, the shape of the wall 33 is trapezoidal in a cross-sectional view. The corners of the trapezoidal shape may be subjected to chamfering, rounding, and the like. However, the shape of the wall 33 is not particularly limited, and may be, for example, rectangular, triangular, approximately semi-circular, approximately semi-elliptical, curved at an upper part, inclined at an upper part, or the like, or may be, for example, stepped in a cross-sectional view.

As a resin material to serve as a base material of the resin molding 30, publicly-known materials, such as thermosetting resins, thermoplastic resins, and the like may be used. In the case of thermoplastic resins, for example, polyphthalamide resin, polybutylene terephthalate (PBT), unsaturated polyester, or the like may be used. In the case of thermosetting resins, for example, epoxy resin, modified epoxy resin, silicone resin, modified silicone resin, or the like may be used. In particular, as the resin material, it is preferable to use a thermosetting resin, such as epoxy resin, silicone resin, or the like having excellent heat resistance and excellent light resistance.

It is preferable to add light scattering particles to the resin material serving as the base material of the resin molding 30. As the light scattering particles, it is preferable to use a member that hardly absorbs light from the light emitting elements and has a large refractive index difference with respect to the resin material serving as the base material. Examples of such light scattering particles include titanium oxide, zinc oxide, silicon oxide, zirconium oxide, aluminum oxide, aluminum nitride, and the like.

As the resin molding 30, dark resin, such as black resin, gray resin, and the like may be used. By using a dark resin as the resin molding 30, it is possible to reduce the deterioration of the light extraction efficiency even if the resin molding 30 discolors. Examples of the dark resin include: carbon, such as acetylene black, activated carbon, graphite, and the like; transition metal oxides, such as iron oxide, manganese dioxide, cobalt oxide, molybdenum oxide, and the like: and a resin containing a filler, such as colored organic pigments and the like. The density of the color, such as black, gray, and the like, may be adjusted based on the addition amount of the filler and the like. Examples of the resin include the resin materials cited as the base material of the resin molding 30. The resin molding 30 may be formed of two types of resins, namely, a dark resin and a white resin containing light scattering particles.

In the resin molding 30, reflective members may be provided on the bottom surfaces and inner lateral surfaces defining the first recess 101 and the second recess 102. As a result, light emitted by the first light emitting element 41, the second light emitting element 42, and the third light emitting element 43, and wavelength-converted light can be efficiently extracted upward, and the light extraction efficiency of the light emitting device 1 can be improved. As the reflective member, a member that hardly transmits and/or absorbs light from the light emitting elements, external light, and/or the like is preferable. It is preferable that the reflective member is white. As a resin material to serve as the base material of the reflective member, the same resin material as the resin material used as the resin molding 30 can be used. The reflective member contains light scattering particles in the resin material serving as the base material thereof. As the light scattering particles, it is preferable to use a member that hardly absorbs light from the light emitting elements and has a large refractive index difference with respect to the resin material serving as the base material. Examples of such light scattering particles include, for example, the same light scattering particles as those contained in the resin molding 30.

When providing the reflective member, it is preferable to provide grooves that, in a top view, surround the first light emitting element 41, the second light emitting element 42, and the third light emitting element 43 in the upper surface of the lead 20. As a result, the grooves serve to block the reflective member, and can reduce deterioration of the light emission efficiency due to the reflective member having contact with the first light emitting element 41, the second light emitting element 42, and the third light emitting element 43.

### First Light Emitting Element, Second Light Emitting Element, and Third Light Emitting Element

The first light emitting element 41, the second light emitting element 42, and the third light emitting element 43 are semiconductor elements that emit light from themselves when a voltage is applied. The shape, size, and the like of the first light emitting element 41, the second light emitting element 42, and the third light emitting element 43 can be selected desirably. Examples of the first light emitting element 41, the second light emitting element 42, and the third light emitting element 43 include an LED chip. The first light emitting element 41, the second light emitting element 42, and the third light emitting element 43 include a semiconductor structure. The semiconductor structure includes an n-type semiconductor layer, a p-type semiconductor layer, and a light emitting layer sandwiched between them. The light emitting layer may have a double heterojunction, single quantum well (SQW), or such structure, or may have a structure including a group of light emitting layers, such as a multiple quantum well (MQW). For example, the light emitting layer may be configured to emit visible light or ultraviolet light.

The semiconductor structure may include a plurality of light emitting parts each including an n-side semiconductor layer, an active layer, and a p-side semiconductor layer. When the semiconductor structure includes a plurality of light emitting parts, the light emitting parts may include well layers having different emission peak wavelengths or may include well layers having the same emission peak wavelength. The term “the same emission peak wavelength” includes emission peak wavelengths different by a few nanometers. The combination of the emission peak wavelengths in the plurality of light emitting parts can be appropriately selected. For example, when the semiconductor structure includes two light emitting parts, examples of the combination of light emitted by the respective light emitting parts include a combination of blue light and blue light, a combination of green light and green light, a combination of red light and red light, a combination of ultraviolet light and ultraviolet light, a combination of blue light and green light, a combination of blue light and red light, a combination of green light and red light, and the like. For example, when the semiconductor structure includes three light emitting parts, examples of the combination of light emitted by the respective light emitting parts include a combination of blue light, green light, and red light. Each light emitting part may include one or more well layers having emission peak wavelengths different from that of the other well layers. The semiconductor structure may be an epitaxial stack structure.

As the first light emitting element 41, for example, a light emitting element configured to emit green light may be used. As the second light emitting element 42 and the third light emitting element 43, for example, light emitting elements configured to emit blue light may be used. However, as the colors of the light emitted by the first light emitting element 41, the second light emitting element 42, and the third light emitting element 43, colors of desirable wavelengths may be selected according to the application. For example, as the blue and green light emitting elements, light emitting elements made of a nitride semiconductor (InxAlyGa1−x−yN (0£x, 0£y, x+y£ 1), GaP, and the like may be used. As the red light emitting element, not only the nitride semiconductor elements, but GaAlAs, AlInGaP, and the like may be used.

The first light emitting element 41 is face-up mounted on the first lead 21. In the example of the light emitting device 1, one element electrode of the first light emitting element 41 is joined to the second lead 22 via the wire 60, and the other element electrode thereof is joined to the third lead 23 via the wire 60. The second light emitting element 42 includes a pair of element electrodes on its upper surface and is face-up mounted on the first lead 21. One element electrode of the second light emitting element 42 is joined to the fourth lead 24 via the wire 60, and the other element electrode is joined to the fifth lead 25 via the wire 60. The third light emitting element 43 includes a pair of element electrodes on its upper surface and is face-up mounted on the first lead 21. One element electrode of the third light emitting element 43 is joined to the first lead 21 via the wire 60, and the other element electrode is joined to the sixth lead 26 via the wire 60. Each light emitting element may be flip-chip mounted, by which it is mounted with the surface, on which electrodes are formed, facing downward.

In the example of the light emitting device 1, the first light emitting element 41, the second light emitting element 42, and the third light emitting element 43 are mounted on the lead 20, but the light emitting device may be a Chip On Board (COB)-type light emitting device in which the light emitting elements are directly disposed on a substrate having electrode terminals. In the COB-type light emitting device, a frame covering the light emitting elements in a top view may be provided on the upper surface of the substrate, and a light transmissive member may be located within the frame. Although the light emitting device 1 according to the present embodiment includes three light emitting elements, namely, the first light emitting element 41, the second light emitting element 42, and the third light emitting element 43, the light emitting device 1 may include four or more light emitting elements.

### Protective Element

The light emitting device 1 may include a protective element. The protective element is, for example, a Zener diode. The protective element may be mounted at any position of the lead 20. The protective element may include, for example, an element electrode on the upper surface of the protective element. For example, the element electrode may be connected to any position of the lead 20 via the wire 60. A varistor may be used as the protective element.

### First Light Transmissive Member

The first light transmissive member 71 may cover a part or the entirety of the inner lateral surface of the frame 32 on the-X side of the wall 33. When the entirety is covered, the light emitted by the first wavelength conversion member included in the first light transmissive member 71 can be intensified. The upper surface of the first light transmissive member 71 may be one of three configurations, namely, flat, recessed with the central part shorter than the peripheral part, or protruded with the central part taller than the peripheral part.

The first light transmissive member 71 includes the first wavelength conversion member having a particulate shape in a base material made of, for example, a light transmissive resin. The same resin material as that used in the resin molding 30 may be used as the base material. In particular, it is preferable to use a silicone resin composition and/or an epoxy resin composition. The first light transmissive member 71 may also contain light scattering particles similar to those in the resin molding 30.

Examples of the base material of the first light transmissive member 71, other than the resin material include sintered bodies of ceramics, glass, and phosphors, and the like. Thus, a high-output light emitting device can have an improved reliability as a light emitting device.

In the first light transmissive member 71, the content of the first wavelength conversion member can be, for example, 30% by mass or greater and 70% by mass or less relative to the total mass of the first light transmissive member 71. The first light transmissive member 71 may include one or a plurality of other wavelength conversion members together with the first wavelength conversion member. In this case, in a cross-sectional view, the area of each of the other wavelength conversion members in the first light transmissive member 71 is smaller than the area of the first wavelength conversion member. When the first light transmissive member 71 includes other wavelength conversion members together with the first wavelength conversion member, the color rendering property of the light emitting device 1 can be improved. Examples of the first wavelength conversion member include a phosphor. Examples of the other wavelength conversion members include phosphors of different types from that of the first wavelength conversion member. Phosphors are excited by the light emitted from the light emitting elements and emit light having wavelengths different from the wavelengths of the light emitted from the light emitting elements. Examples of the phosphors include yttrium aluminum garnet-based phosphors (for example, (Y, Gd)3(Al, Ga)5O12:Ce), lutetium aluminum garnet-based phosphors (for example, Lu3(Al, Ga)5O12:Ce), terbium aluminum garnet-based phosphors (for example, Tb3(Al, Ga)5O12:Ce), CCA-based phosphors (for example, Ca10(PO4)6Cl2:Eu), BAM-based phosphors (for example, BaMgAl10O17:Eu2+), SAE-based phosphors (for example, Sr4Al14O25:Eu), chlorosilicate-based phosphors (for example, Ca8MgSi4O16Cl2:Eu), silicate-based phosphors (for example, (Ba, Sr, Ca, Mg)2SiO4:Eu), oxynitride-based phosphors, such as β sialon-based phosphors (for example, (Si, Al)3(O, N)4:Eu), α sialon-based phosphors (for example, Ca(Si, Al)12(O, N)16:Eu), and the like, LSN-based phosphors (for example, (La, Y)3Si6N11:Ce), BSESN-based phosphors (for example, (Ba, Sr)2Si5N8:Eu), SLA-based phosphors (for example, SrLiAl3N4:Eu), nitride-based phosphors, such as CASN-based phosphors (for example, CaAlSiN3:Eu), SCASN-based phosphors (for example, (Sr, Ca)AlSiN3:Eu), and the like, fluoride-based phosphors, such as KSF-based phosphors (for example, K2SiF6:Mn), KSAF-based phosphors (for example, K2(Si1−xAlx)F6−x:Mn where x satisfies 0<x<1), MGF phosphors (for example, 3.5MgO·0.5MgF2·GeO2:Mn), and the like, quantum dots having a perovskite structure (for example, (Cs, FA, MA)(Pb, Sn)(F, Cl, Br, I)3 where FA and MA represent formamidinium and methylammonium, respectively), Group II-VI quantum dots (for example, CdSe), Group III-V quantum dots (for example, InP), quantum dots having a chalcopyrite structure (for example, (Ag, Cu)(In, Ga)(S, Se)2), and the like.

As the first wavelength conversion member, for example, a red phosphor having a wide half width can be used. Thus, the color rendering property of the light emitting device 1 can be improved. The half-width of the red phosphor is, for example, from 60 nm or greater and 100 nm or less, and preferably from 70 nm or greater and 85 nm or less. Generally, the half-width of the emission spectrum of a light emitting device using a red phosphor tends to be wider than that of the emission spectrum of a red light emitting element. Therefore, compared with red light extraction from a red light emitting element, use of a red phosphor as the first wavelength conversion member better facilitates improvement of the color rendering property of the light emitting device 1.

Examples of the red phosphor include KSF, SCASN, CASN, and the like. The composition of KSF is, for example, K2SiF6:Mn. The composition of SCASN is, for example, (Sr, Ca)AlSiN3:Eu. The composition of CASN is, for example, CaAlSiN3:Eu. When the first light emitting element 41 emits green light and the second light emitting element 42 emits blue light, it is preferable to use KSF as the first wavelength conversion member. KSF is less excited by green light than SCASN and CASN. Therefore, use of KSF as the first wavelength conversion member can help secure a large difference between the chromaticity obtained when only the first light emitting element 41 emits light and the chromaticity obtained when only the second light emitting element 42 emits light. This facilitates widening the color gamut of the light emitting device.

### Second Light Transmissive Member

The second light transmissive member 72 may cover a part or the entirety of the inner lateral surface of the frame 32 on the +X side of the wall 33. The upper surface of the second light transmissive member 72 may be flat, or recessed with the central part shorter than the peripheral part.

The second light transmissive member 72 is composed of, for example, a light transmissive resin. As a resin material to serve as the base material of the second light transmissive member 72, the same resin material as that used in the first light transmissive member 71 may be used. The second light transmissive member 72 may contain light scattering particles. As the light scattering particles, the same light scattering particles as those that can be contained in the first light transmissive member 71 can be used.

[Method of Manufacturing Light Emitting Device] An example of a method of manufacturing the light emitting device 1 will be described below.

### Lead Preparation Step

A lead preparation step is a step of preparing the lead 20 including the first lead 21, the second lead 22, the third lead 23, the fourth lead 24, the fifth lead 25, and the sixth lead 26. The lead 20 can be formed by etching or pressing a thin metal plate. A plated layer may be formed on the surface of the lead 20 by electroless plating or electroplating, as needed.

### Resin Molding Forming Step

The resin molding forming step is a step of forming the resin molding 30 that fixes and holds the first lead 21, the second lead 22, the third lead 23, the fourth lead 24, the fifth lead 25, and the sixth lead 26. In this step, for example, the lead 20 including the first lead 21, the second lead 22, the third lead 23, the fourth lead 24, the fifth lead 25, and the sixth lead 26 is set in a mold for package manufacture, and a resin is injected into the mold and cured. This results in the support 10 including the lead 20 and the resin molding 30.

### Light Emitting Element Placing Step

The light emitting element placing step is a step of placing the first light emitting element 41, the second light emitting element 42, and the third light emitting element 43 on the first lead 21. In this step, for example, the first light emitting element 41, the second light emitting element 42, and the third light emitting element 43 are face-up mounted on the first lead 21 exposed on the bottom surface of the first recess 101 or the second recess 102, with the surfaces of the light emitting elements opposite to the surfaces, on which the electrodes are formed, serving as the mounting surfaces, such that the surfaces, on which the electrodes are formed, can be used as the main light extraction surfaces.

### Wire Connecting Step

A wire connecting step is a step of forming the wires 60 for electrically connecting the first light emitting element 41, the second light emitting element 42, and the third light emitting element 43 to appropriate positions on the lead 20. After the wires 60 are formed, the aforementioned protective film may be formed so as to cover the lead, the light emitting elements, and the wires. When the first light emitting element 41, the second light emitting element 42, and/or the third light emitting element 43 are face-down mounted, the wire connecting step does not need to be performed.

### First Light Transmissive Member Placing Step

The first light transmissive member placing step is a step of placing the first light transmissive member 71 so as to cover the upper and lateral surfaces of the first light emitting element 41 and the second light emitting element 42. In this step, a resin, which becomes the first light transmissive member 71, is placed so as to cover the upper and lateral surfaces of the first light emitting element 41 and the second light emitting element 42 by, for example, printing, potting, spraying, or the like. Thereafter, the resin is cured at a temperature of, for example, 120° C. or higher and 200° C. or lower to form the first light transmissive member 71. The first light transmissive member 71 may be placed by pasting a sheet-like or block-like resin member on the upper surfaces of the light emitting elements with an adhesive or the like.

### Second Light Transmissive Member Placing Step

A second light transmissive member placing step is a step of placing the second light transmissive member 72 so as to cover the upper and lateral surfaces of the third light emitting element 43. In this step, like the first light transmissive member 71, the second light transmissive member 72 can be placed by placing a resin at a predetermined position and curing the resin by heating. The second light transmissive member 72 may be placed by pasting a sheet-like or block-like resin member to the upper surface of the light emitting element with an adhesive or the like.

The first light transmissive member 71 or the second light transmissive member 72 may be placed earlier than the other, or they may be placed at the same time. The support 10 formed in the resin molding forming step may be an assembly in which supports 10 constituting a plurality of light emitting devices, respectively, are joined. When the support 10 is an assembly, the first leads 21, the second leads 22, the third leads 23, the fourth leads 24, the fifth leads 25, and the sixth leads 26 of the plurality of light emitting devices are continuous. When the support 10 is an assembly, the resin moldings 30 of the plurality of light emitting devices are continuous. When the support 10 is an assembly, the method of manufacturing the light emitting device 1 includes a singulation step of singulating the assembly into the respective light emitting devices.

Further, in the method of manufacturing the light emitting device 1, other steps may be included between or before the steps as long as no contradiction occurs between the steps described above. For example, a foreign matter removing step of removing foreign matter mixed during the manufacture may be included.

Moreover, in the method of manufacturing the light emitting device 1, some steps are not limited in the order, and may be brought forward or backward.

The lead preparation step, the resin molding forming step, and/or the like may be performed by the manufacturer itself, or a lead in which grooves are formed, and the like may be prepared by transfer and acquisition including purchase.

### First Modification

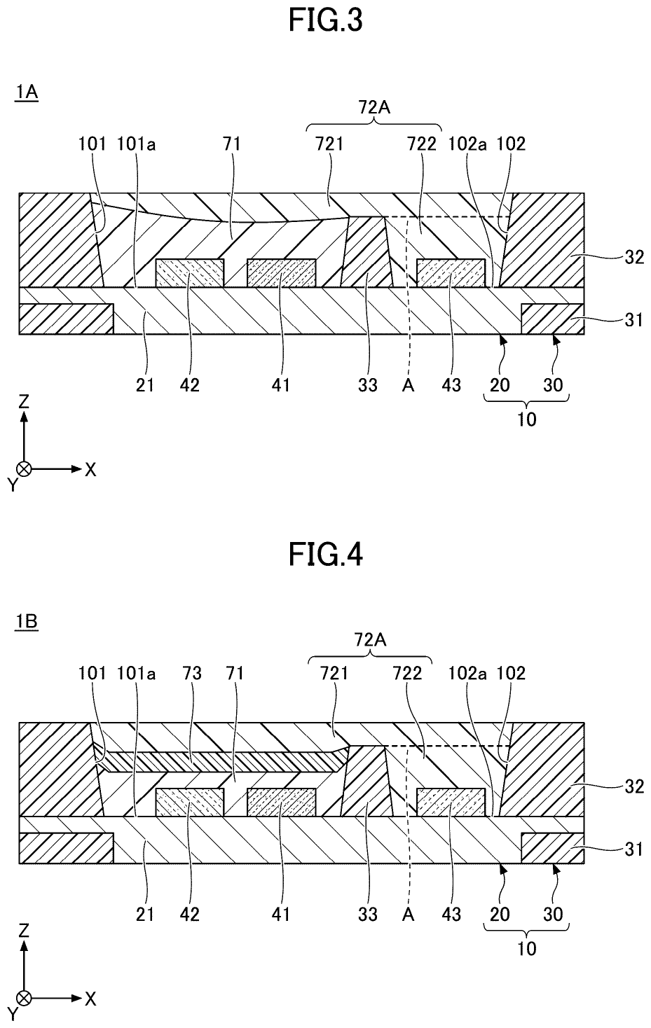

FIG. 3 is a schematic cross-sectional view showing a light emitting device according to a first modification of the first embodiment. A light emitting device 1A shown in FIG. 3 differs from the light emitting device 1 in that the second light transmissive member 72 is replaced by a second light transmissive member 72A.

Unlike in the light emitting device 1, in the light emitting device 1A, the height of the wall 33 with respect to the upper surface of the lead 20 is lower than the height of the frame 32. It is preferable that the height of the wall 33 with respect to the upper surface of the lead 20 is higher than the height of the upper surfaces of the first light emitting element 41, the second light emitting element 42, and the third light emitting element 43. This makes it easier for the first light transmissive member 71 to cover the upper surfaces of the first light emitting element 41 and the second light emitting element 42.

The second light transmissive member 72A covers the upper surface of the first light emitting element 41, the upper surface of the second light emitting element 42, the upper surface of the third light emitting element 43, and the upper surface of the wall 33. In the illustrated example, the second light transmissive member 72A includes a first light transmissive part 721 overlapping the first light emitting element 41, the second light emitting element 42, the third light emitting element 43, and the wall 33 in a top view, and a second light transmissive part 722 overlapping the third light emitting element 43 in a top view. The second light transmissive part 722 is located in the second recess 102. The first light transmissive part 721 is located above the first light transmissive member 71 located in the first recess 101, and above the second light transmissive part 722 located in the second recess 102.

The broken line A is an imaginary line indicating the boundary between the first light transmissive part 721 and the second light transmissive part 722 in the height direction. The broken line A may be flush with the upper surface of the wall 33. The second light transmissive part 722 is located on the lead 20 side of the broken line A in the second recess 102. The first light transmissive part 721 and the second light transmissive part 722 may be integrated or separate.

Thus, in the light emitting device 1A, the second light transmissive member 72A includes the first light transmissive part 721 overlapping the first light emitting element 41, the second light emitting element 42, the third light emitting element 43, and the wall 33 in a top view. Accordingly, the light emitted from the first light emitting element 41 and the second light emitting element 42 and the light emitted from the third light emitting element 43 are easily mixed above the wall 33, and therefore, the color mixing performance above the wall 33 is improved.

It is preferable that the first light emitting element 41 and the third light emitting element 43 are arranged in the first direction X, and that the length of the third light emitting element 43 in the first direction X is shorter than the length of the third light emitting element 43 in the second direction Y orthogonal to the first direction X. That is, it is preferable that the third light emitting element 43 is arranged such that its longer direction is aligned with the second direction Y.

If the length of the third light emitting element 43 in the first direction X is longer than the length of the third light emitting element 43 in the second direction Y orthogonal to the first direction X, The light from an end of the third light emitting element 43 in the +X direction in FIG. 3 toward a region above the wall 33 enters the upper surface of the first light transmissive part 721 located above the wall 33 at a relatively large angle of incidence, and thus may be totally reflected on the upper surface of the first light transmissive part 721. Allowing a part of the light emitted from the third light emitting element 43 to be totally reflected on the upper surface of the first light transmissive part 721 may result in reduction in the light extraction efficiency of the light emitting device. Moreover, when the light totally reflected on the upper surface of the first light transmissive part 721 enters the first light transmissive member 71, the first wavelength conversion member might be excited. This may cause deviation of the light emitted from the light emitting device from the desired chromaticity.

In the light emitting device 1A, with the length of the third light emitting element 43 in the first direction X being shorter than the length of the third light emitting element 43 in the second direction Y orthogonal to the first direction X, light emitted from the third light emitting element 43 and totally reflected on the upper surface of the first light transmissive part 721 can be reduced. Thus, the light extraction efficiency of the light emitting device 1A can be improved. Moreover, the first wavelength conversion member is less likely to be excited by light emitted from the third light emitting element 43, so that the light emitted from the light emitting device 1A is less likely to be deviated from the desired chromaticity.

### Second Modification

FIG. 4 is a schematic cross-sectional view showing a light emitting device according to a second modification of the first embodiment. A light emitting device 1B shown in FIG. 4 differs from the light emitting device 1A in that it includes a third light transmissive member 73.

The third light transmissive member 73 is located between the first light transmissive member 71 and the first light transmissive part 721 in the first recess 101. The third light transmissive member 73 includes a second wavelength conversion member having an emission peak wavelength shorter than the emission peak wavelength of the first light emitting element 41.

The third light transmissive member 73 includes a base material made of, for example, a light transmissive resin, and the second wavelength conversion member having a particulate shape and contained in the base material. As the resin material to serve as the base material of the third light transmissive member 73, the same resin material as that used in the first light transmissive member 71 may be used. The third light transmissive member 73 may contain light scattering particles. As the light scattering particles, the same light scattering particles as those that can be contained in the first light transmissive member 71 may be used.

For example, in the light emitting device 1A shown in FIG. 3, light emitted from the third light emitting element 43 and totally reflected on the upper surface of the first light transmissive part 721 being reduced does not exclude some light being totally reflected. In this case, as described above, the light extraction efficiency of the light emitting device might deteriorate, and/or the light emitted from the light emitting device might deviate from the desired chromaticity.

In the light emitting device 1B, with the third light transmissive member 73 located between the first light transmissive member 71 and the first light transmissive part 721, light emitted from the third light emitting element 43 and reflected on the upper surface of the first light transmissive part 721 can be inhibited from impinging on the first light transmissive member 71. Accordingly, excitation of the first wavelength conversion member is less likely to occur, which can reduce deviation of the light emitted from the light emitting device 1B from the desired chromaticity.

For example, when the first light emitting element 41 emits green light and the third light emitting element 43 emits blue light, a blue phosphor can be used as the second wavelength conversion member contained in the third light transmissive member 73. Examples of the blue phosphor include CCA, BAM, and the like. The composition of CCA is, for example, Ca10(PO4)6Cl2:Eu. The composition of BAM is, for example, BaMgAl10O17:Eu2+.

The third light transmissive member 73 may contain a blue pigment. When the third light transmissive member 73 contains a blue pigment, the third light transmissive member 73 may or may not contain the second wavelength conversion member.

### Third Modification

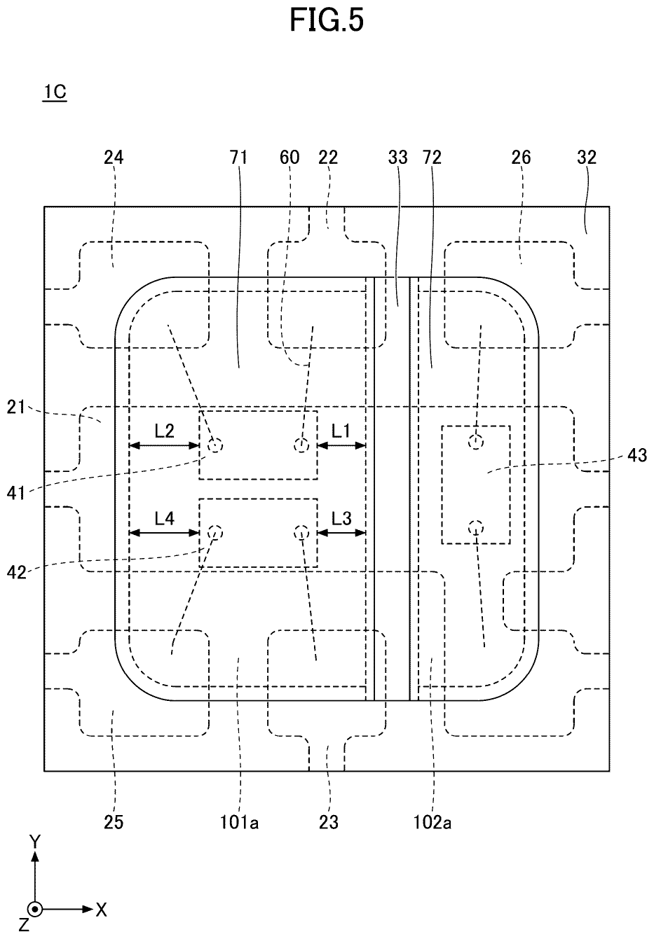

FIG. 5 is a schematic top view showing a light emitting device according to a third modification of the first embodiment. A light emitting device 1C shown in FIG. 5 differs from the light emitting device 1 in the location of the first light emitting element 41 and the second light emitting element 42.

In the light emitting device 1C, the first light emitting element 41 and the second light emitting element 42 are arranged in the second direction Y. The first light emitting element 41 and the second light emitting element 42 are rectangular in a top view, their longer sides are parallel with the first direction X, and their shorter sides are parallel with the second direction Y. An imaginary straight line connecting the center of the first light emitting element 41 and the center of the second light emitting element 42 in a top view can be parallel with the second direction Y. The longer sides of the first light emitting element 41 and the second light emitting element 42 face each other. With such an arrangement of the first light emitting element 41 and the second light emitting element 42, it is possible to reduce the size of the light emitting device 1C in the first direction X. Further, the longer sides of the first light emitting element 41 and the second light emitting element 42 face each other, which allows for improvement in the color mixing performance.

It is preferable that the inner lateral surface of the frame 32 defining the first recess 101, the first light emitting element 41, the wall 33, and the third light emitting element 43 are arranged in order in the first direction X, and that the length L1 from the first light emitting element 41 to the wall 33 in the first direction X is shorter than the length L2 from the first light emitting element 41 to the inner lateral surface of the frame 32 defining the first recess 101 in the first direction X in a top view. This allows the first light emitting element 41 and the third light emitting element 43 to be located close to each other, and thus allows improvement in the color mixing performance.

Similarly, it is preferable that the inner lateral surface of the frame 32 defining the first recess 101, the second light emitting element 42, the wall 33, and the third light emitting element 43 are arranged in order in the first direction X, and that the length L3 from the second light emitting element 42 to the wall 33 is shorter than the length L4 from the second light emitting element 42 to the inner lateral surface of the frame 32 defining the first recess 101 in the first direction X in a top view. This allows the second light emitting element 42 and the third light emitting element 43 to be located close to each other, thereby improving the color mixing performance.

### Fourth Modification

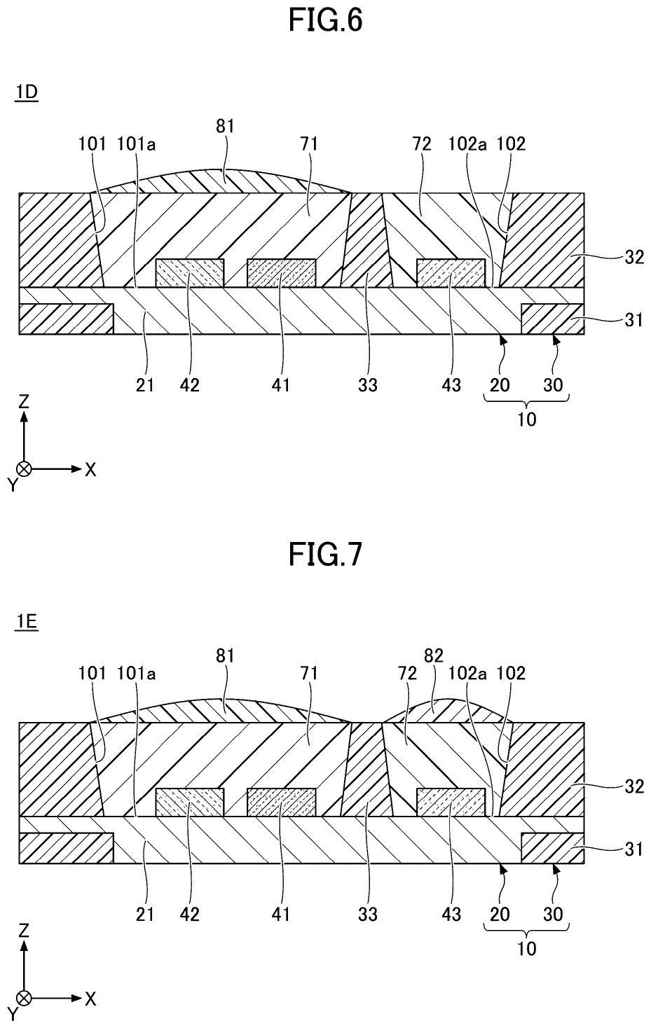

FIG. 6 is a schematic cross-sectional view (1) showing a light emitting device according to a fourth embodiment of the first embodiment. A light emitting device 1D shown in FIG. 6 differs from the light emitting device 1 in that it includes a first light diffusing member 81.

The first light diffusing member 81 overlaps the first light emitting element 41 in a top view, and at least a part of the first light diffusing member 81 is located above the wall 33. The entirety of first light diffusing member 81 may be located above the wall 33. The first light diffusing member 81 covers the upper surface of the first light transmissive member 71. The first light diffusing member 81 may have various shapes, and, for example, may have a protruded shape with the central part taller than the peripheral part.

The first light diffusing member 81 has a light transmitting property and a light diffusing property, and contains light scattering particles in a base material made of, for example, a light transmissive resin. As the resin material to serve as the base material of the first light diffusing member 81, the same resin material as that used in the first light transmissive member 71 may be used. As the light scattering particles, the same light scattering particles as those that can be contained in the first light transmissive member 71 may be used.

With the first light diffusing member 81, light incident on the first light diffusing member 81 is emitted from the first light diffusing member 81 while being diffused, and thus is easily mixed with light emitted from the second light transmissive member 72. Therefore, the color mixing performance can be improved.

FIG. 7 is a schematic cross-sectional view (2) showing a light emitting device according to a fourth modification of the first embodiment. A light emitting device 1E shown in FIG. 7 differs from the light emitting device 1D in that it includes a second light diffusing member 82 in addition to the first light diffusing member 81.

The second light diffusing member 82 overlaps the third light emitting element 43 in a top view, at least a part of the second light diffusing member is located above the wall 33, and the second light diffusing member 82 is located apart from the first light diffusing member 81. The entirety of the second light diffusing member 82 may be located above the wall 33. The second light diffusing member 82 covers the upper surface of the second light transmissive member 72. The second light diffusing member 82 may have various shapes, and may have, for example, a protruded shape with the central portion taller than the peripheral portion.

The second light diffusing member 82 has a light transmitting property and a light diffusing property, and contains light scattering particles in a base material made of, for example, a light transmissive resin. As the resin material to serve as the base material of the second light diffusing member 82, the same resin material as that used in the first light transmissive member 71 may be used. As the light scattering particles, the same light scattering particles as those that can be contained in the first light transmissive member 71 can be used.

With the second light diffusing member 82, light incident on the second light diffusing member 82 is emitted from the second light diffusing member 82 while being diffused, and thus is easily mixed with light emitted from the first light diffusing member 81 while being diffused. Therefore, the color mixing performance can be further improved relative to the light emitting device 1D.

Moreover, with the second light diffusing member 82 at a position apart from the first light diffusing member 81, light from the third light emitting element 43 is less likely to impinge on the first light transmissive member 71 through the first light diffusing member 81 and the second light diffusing member 82. Accordingly, the first wavelength conversion member is less likely to be excited, which can reduce deviation of light emitted from the light emitting device 1E from the desired chromaticity.

In the light emitting devices 1D and 1E, the height of the wall 33 with respect to the upper surface of the lead 20 is the same as the height of the frame 32. However, the height of the wall 33 may be lower than the height of the frame 32 as shown in FIG. 3. In this case, light emitted from the first light emitting element 41 and the second light emitting element 42 easily mixes with light emitted from the third light emitting element 43 above the wall 33, thereby further improving the color mixing performance.

### Fifth Modification

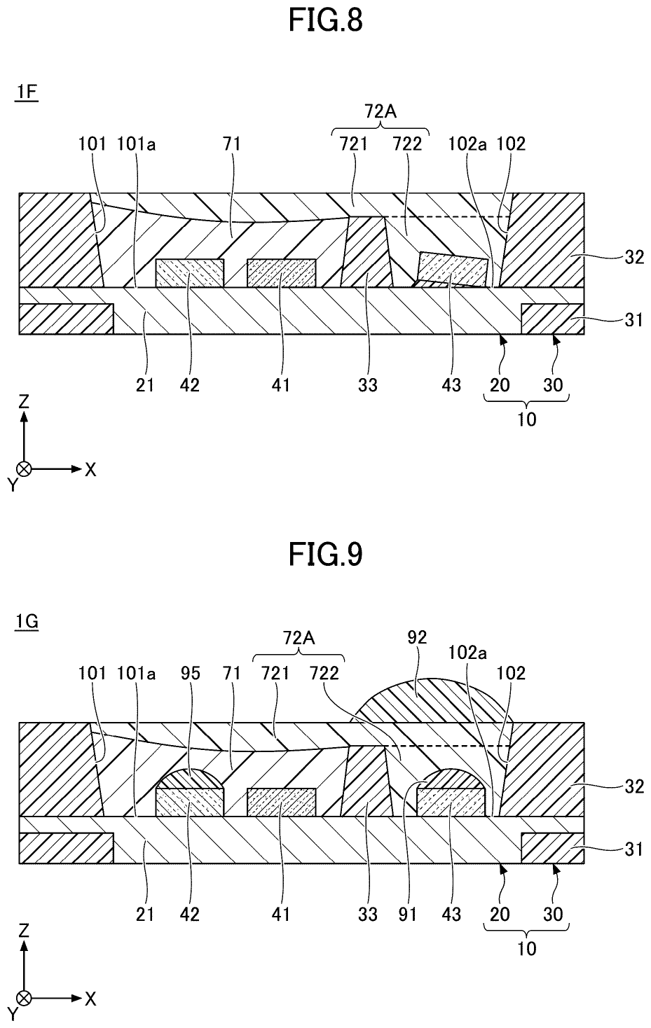

FIG. 8 is a schematic cross-sectional view showing a light emitting device according to a fifth modification of the first embodiment. A light emitting device 1F shown in FIG. 8 differs from the light emitting device 1A in that the third light emitting element 43 is inclined with respect to the upper surface of the lead 20. In the light emitting device 1A shown in FIG. 3, the third light emitting element 43 is not inclined with respect to the upper surface of the lead 20.

In the light emitting device 1F, the third light emitting element 43 can be disposed while being inclined with respect to the upper surface of the lead 20 such that the-X side of the upper surface of the third light emitting element 43 is higher than the +X side. This contributes to avoiding light from the third light emitting element 43 impinging on the first light transmissive member 71 by being reflected on the upper surface of the second light transmissive member 72A. This reduces the chance of the first wavelength conversion member being excited, and can reduce deviation of light emitted from the light emitting device 1F from the desired chromaticity.

Alternatively, the third light emitting element 43 may be disposed while being inclined with respect to the upper surface of the lead 20 such that the-X side of the upper surface of the third light emitting element 43 is lower than the +X side. This can further improve the color mixing performance of the light emitting device. To incline the third light emitting element 43 with respect to the upper surface of the lead 20, for example, the amount of the adhesive on the −X side and the amount of the adhesive on the +X side may be varied when adhesively joining the third light emitting element 43 to the upper surface of the lead 20.

### Sixth Modification

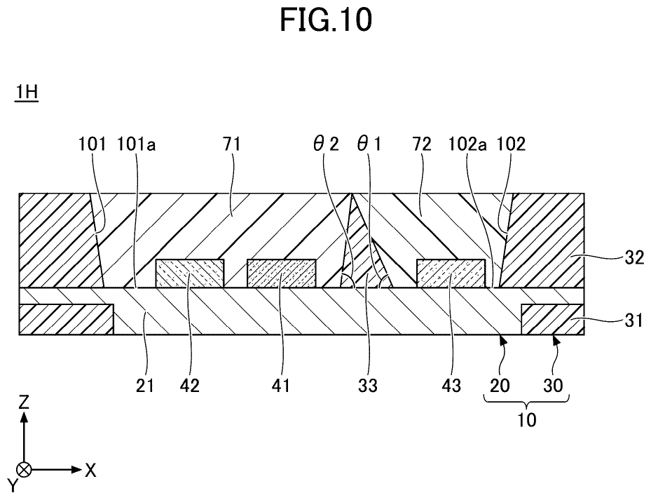

FIG. 9 is a schematic cross-sectional view showing a light emitting device according to a sixth modification of the first embodiment. A light emitting device 1G shown in FIG. 9 differs from the light emitting device 1A in that it includes a first light control part 91 and a second light control part 92, and a fourth light transmissive member 95.

The first light control part 91 covers the upper surface of the third light emitting element 43. The second light control part 92 covers the upper surface of the second light transmissive member 72A above the second recess 102 and the wall 33. The second light control part 92 does not cover the upper surface of the second light transmissive member 72A above the first recess 101. The first light control part 91 and the second light control part 92 may have various shapes, and, for example, may have a convex lens shape with the central part taller than the peripheral part. The second light control part 92 and the second light transmissive member 72A may be integrated or separate.

The first light control part 91 and the second light control part 92 have a light transmitting property and are composed of, for example, a light transmissive resin. As the resin material to serve as the base material of the first light control part 91 and the second light control part 92, the same resin material as that used in the first light transmissive member 71 can be used. The first light control part 91 and the second light control part 92 may contain light scattering particles. As the light scattering particles, the same light scattering particles as those that can be contained in the first light transmissive member 71 can be used.

By providing the first light control part 91 and the second light control part 92 in this way, it is possible to perform light distribution control. The lateral surfaces of the third light emitting element 43 may be covered with a reflecting member. This makes the third light emitting element 43 resemble a point light source, which facilitates the light distribution control by the first light control part 91. Either one of the first light control part 91 and the second light control part 92 may be provided.

In addition, with the first light control part 91 having a convex lens shape located on the upper surface of the third light emitting element 43, the light emitted from the third light emitting element 43 is condensed by the first light control part 91, which contributes to avoiding light output via the first light control part 91 impinging on the first light transmissive member 71 by being reflected on the upper surface of the second light transmissive member 72A. This reduces chances of the first wavelength conversion member being excited, and can reduce deviation of the light emitted from the light emitting device 1G from the desired chromaticity.

Furthermore, by no light control part having a convex shape being provided on the upper surface of the first light emitting element 41, it becomes easier for the light emitted from the first light emitting element 41 to enter the third light emitting element 43 side, thereby improving the color mixing performance.

The fourth light transmissive member 95 covers the upper surface of the second light emitting element 42. The fourth light transmissive member 95 may have various shapes, and may have, for example, a convex shape with the central part taller than the peripheral part.

The fourth light transmissive member 95 has a light transmitting property, and contains a third wavelength conversion member having a particulate shape in its base material made of, for example, a light transmissive resin. As the resin material to serve as the base material of the fourth light transmissive member 95, the same resin material as that used in the first light transmissive member 71 can be used. The fourth light transmissive member 95 may contain light scattering particles. As the light scattering particles, the same light scattering particles as those that can be contained in the first light transmissive member 71 can be used.

The third wavelength conversion member has an emission peak wavelength longer than the emission peak wavelength of the second light emitting element 42. For example, when the second light emitting element 42 emits blue light, the third wavelength conversion member may be a red phosphor. This makes it possible to increase redness in the light emitted from the light emitting device 1G, thereby improving the color rendering property.

### Seventh Modification

FIG. 10 is a schematic cross-sectional view showing a light emitting device according to a seventh modification of the first embodiment. A light emitting device 1H shown in FIG. 10 differs from the light emitting device 1 in the shape of the wall 33 in a cross-sectional view.

In the light emitting device 1H, the inclination angles of an inclined surface of the wall 33 on the +X side and an inclined surface thereof on the −X side are different in a cross-sectional view. In the cross-sectional view, the angle θ1 formed between the upper surface of the lead 20 and the inclined surface of the wall 33 on the +X side is smaller than the angle θ2 formed between the upper surface of the lead 20 and the inclined surface of the wall 33 on the −X side. As a result, the light emitted from the third light emitting element 43 is reflected on the inclined surface of the wall 33 on the +X side and tends to be condensed toward the center of the frame 32 in a top view, thereby improving the color mixing performance. The angle θ1 between the upper surface of the lead 20 and the inclined surface of the wall 33 on the +X side may be greater than the angle θ2 between the upper surface of the lead 20 and the inclined surface of the wall 33 on the −X side.

The preferred embodiments have been described in detail above. However, the above-described embodiments are non-limiting, and various modifications and substitutions are applicable to the above-described embodiments without departing from the scope of description in the claims.

What is claimed is:

1. A light emitting device, comprising:
a support defining a first recess and a second recess and comprising a wall that partitions between the first recess and the second recess,
an area of a first bottom surface defining a bottom of the first recess being greater than an area of a second bottom surface defining a bottom of the second recess in a top view of the light emitting device;
a first light emitting element located in the first recess;
a second light emitting element located in the first recess;
a third light emitting element located in the second recess;
a first light transmissive member located in the first recess, the first light transmissive member including a first wavelength conversion member having an emission peak wavelength longer than an emission peak wavelength of the first light emitting element, the first light transmissive member overlapping the first light emitting element and the second light emitting element in the top view and located apart from the third light emitting element in the top view; and
a second light transmissive member located in the second recess and overlapping the third light emitting element in the top view,
wherein the first light emitting element, the second light emitting element, and the third light emitting element are drivable independently from each other, and
wherein the emission peak wavelength of the first light emitting element is longer than an emission peak wavelength of the second light emitting element and an emission peak wavelength of the third light emitting element.

2. The light emitting device according to claim 1,
wherein the second light transmissive member includes a first light transmissive part overlapping the first light emitting element, the second light emitting element, the third light emitting element, and the wall in the top view.

3. The light emitting device according to claim 2, further comprising:
a third light transmissive member located between the first light transmissive member and the first light transmissive part, wherein the third light transmissive member includes a second wavelength conversion member having an emission peak wavelength shorter than the emission peak wavelength of the first light emitting element.

4. The light emitting device according to claim 1, wherein
the first light emitting element and the third light emitting element are arranged in a first direction, and
a length of the third light emitting element in the first direction is shorter than a length of the third light emitting element in a second direction orthogonal to the first direction.

5. The light emitting device according to claim 1,
wherein the first light emitting element and the second light emitting element are arranged in a second direction.

6. The light emitting device according to claim 1, wherein
the first recess and the second recess are located inward of a frame of the support in the top view,
an inner lateral surface of the frame defining a lateral side of the first recess, the first light emitting element, the wall, and the third light emitting element are arranged in order in a first direction, and
in the top view, a length from the first light emitting element to the wall in the first direction is shorter than a length from the first light emitting element to the inner lateral surface in the first direction.

7. The light emitting device according to claim 1, further comprising
a first light diffusing member overlapping the first light emitting element in the top view, wherein, when viewed in a direction perpendicular to the top view, at least a part of the first light diffusing member is located above the wall.

8. The light emitting device according to claim 7, further comprising:
a second light diffusing member overlapping the third light emitting element in the top view, wherein
at least a part of the second light diffusing member is located above the wall, and
the second light diffusing member is located apart from the first light diffusing member.
